(19) United States
(12) Patent Application Publication
(10) Pub. No.: US 2005/0029633 A1
(43) Pub. Date: Feb. 10, 2005

(54) Optical semiconductor device and method of manufacturing the same

(75) Inventor: Masaru Yumura, Fukuoka-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/879,189

(22) Filed: Jun. 30, 2004

(30) Foreign Application Priority Data
Jul. 11, 2003 (JP) P2003-195679

(51) Int. Cl. H01L 23/495

(52) U.S. Cl. 257/666

(57) ABSTRACT

An optical semiconductor device comprises a lead frame, a mount bed integrated with the lead frame, an optical semiconductor element mounted on the mount bed with an adhesive agent interposed therebetween, and a light-transmitting resin for sealing the optical semiconductor element. A surface of the mount bed mounting the optical semiconductor element has a concave portion and has one end of a discharge hole penetrating the mount bed in the concave portion.

### CROSS-REFERENCE TO RELATED APPLICATIONS

This application is based upon and claims the benefit of priority from the prior Japanese Patent Application No. 2003-195679, filed Jul. 11th 2003, the entire contents of which are incorporated herein by reference.

### 1. FIELD OF THE INVENTION

The present invention relates to an optical semiconductor device and a method of manufacturing the same, particularly to an optical semiconductor device using a mount bed.

### 2. BACKGROUND OF THE INVENTION

Recently, in an optical semiconductor device such as a photocoupler and a photorelay, there has been used a mount bed for insulating a light receiving element and a lead frame, the mount bed being formed of an injection resin.

FIG. 4 shows a cross-sectional view of a conventional optical semiconductor device. A mount bed 102 is integrally formed with a lead frame 101 and a light receiving element 104 is mounted thereon with an adhesive agent 103 interposed therebetween. On lead frame 101, a MOS-FET 108 connected to light receiving element 104 is mounted. A light emitting element 111 which is mount-bonded onto a lead frame 109 is placed so as to face light receiving element 104 through a light-transmitting resin 112. The components described above are covered with a mold resin 113.

Such an optical semiconductor device as described above functions as a high-speed switching device and the like by converting light from light emitting element 111 into an electrical signal in light receiving element 104 and driving MOS-FET 108 in an output part.

### SUMMARY OF THE INVENTION

An optical semiconductor device according to an embodiment of the present invention comprises a lead frame, a mount bed integrated with the lead frame, an optical semiconductor element mounted on the mount bed with an adhesive agent interposed therebetween, and a light-transmitting resin for sealing the optical semiconductor element, wherein a surface of the mount bed mounting the optical semiconductor element has a concave portion and has one end of a discharge hole penetrating the mount bed in the concave portion.

A method for manufacturing an optical semiconductor device according to an embodiment of the present invention, comprises integrally forming a lead frame having a predetermined shape and a mount bed by injection molding, forming a discharge hole penetrating the mount bed at a predetermined position, forming a concave portion on an upper surface of the mount bed including one end of the discharge hole applying an adhesive agent onto the upper surface of the mount bed including the concave portion, mounting an optical semiconductor element on the adhesive agent, and sealing the optical semiconductor element with a light-transmitting resin and heat curing the resin.

### BRIEF DESCRIPTION OF THE DRAWINGS

FIG. 1 is a cross-sectional view of an optical semiconductor device according to an embodiment of the present invention.

FIG. 2A is a top view of a light emitting element side of the optical semiconductor device according to the embodiment of the present invention.

FIG. 2B is a top view of a light receiving element side of the optical semiconductor device according to the embodiment of the present invention.

FIG. 3 is a view showing electrical connection of the optical semiconductor device according to the embodiment of the present invention.

FIG. 4 is a cross-sectional view of a conventional optical semiconductor device.

FIG. 5 is a view showing an ejector pin mark of a mount bed part of an optical semiconductor device.

FIG. 6 is a cross-sectional view of an optical semiconductor device.

### DETAILED DESCRIPTION OF THE INVENTION

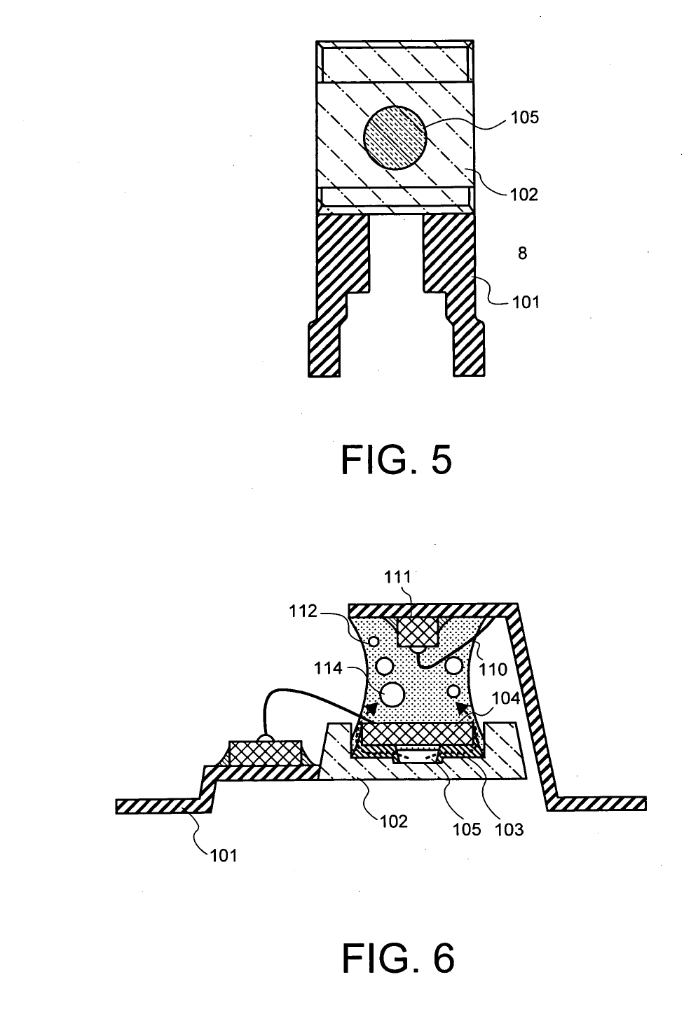

For example, a mount bed 102 of an optical semiconductor device shown in FIG. 6 is integrally formed with a lead frame in such a manner that, after a resin is poured into a predetermined mold and is heat cured, the resin is removed from the mold. Since the mold and the lead frame are in close contact with each other, the lead frame is removed from the mold by use of an ejector pin to push the lead frame off. In this event, the ejector pin leaves a mark (concave portion 105) as shown in FIG. 5.

As shown in FIG. 6, an adhesive agent 103 is applied on mount bed 102 including concave portion 105, and a light receiving element 104 is mounted thereon. Thereafter, a light-transmitting resin 112 is applied for sealing and is heat cured. However, since adhesive agent 103 has predetermined viscosity, concave portion 105 is not completely filled. Accordingly, air is trapped between light receiving element 104 and mount bed 102. This trapped air moves into light-transmitting resin 112 and remains as air bubbles 114. Thus, optical coupling properties and withstand pressure between input and output are lowered. Consequently, there arises a problem that product properties and reliability are lowered.

The concave portion can be completely filled with the resin by lowering the viscosity of the adhesive agent. However, the applied amount varies and productivity is lowered. Meanwhile, as to a light-emitting display device, there is a technology of discharging air bubbles through an insertion hole provided in a surface of a LED chip mounting substrate, the air bubbles being generated in injection of a resin which forms a light guiding part and remaining in the resin (for example, Japanese Patent Laid-Open No. 2000-12576). However, there are no suggestions given to the problem in application of the adhesive agent.

In order to solve the foregoing problem, an embodiment of the present invention will be described below with reference to the drawings.

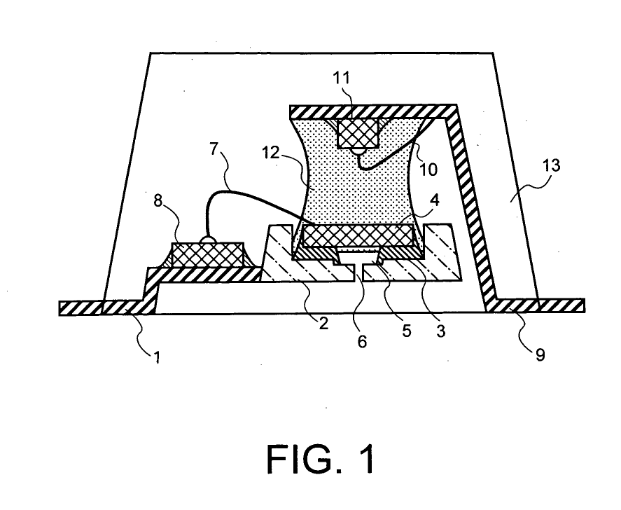

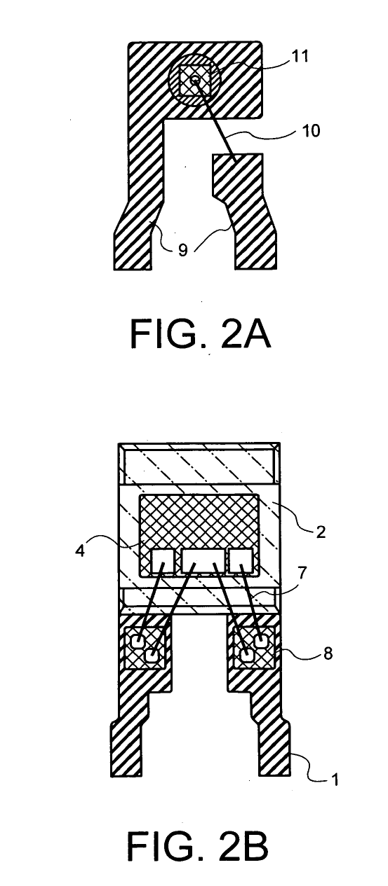

FIG. 1 shows a cross-sectional view of an optical semiconductor device according to this embodiment. FIG. 2A shows a top view of a light emitting element side and FIG. 2B shows a top view of a light receiving element side.

As shown in FIG. 1, a mount bed 2 is integrally formed with a lead frame 1 and a light receiving element 4 with a control circuit function is mounted thereon with an adhesive agent 3 interposed therebetween. On a light receiving element 4 mounting surface of mount bed 2, a concave portion 5 is formed and a discharge hole 6 penetrating mount bed 2 from a bottom of concave portion 5 is formed.

On lead frame 1, a MOS-FET 8 connected to light receiving element 4 by wire 7 is mounted. A light emitting element 11 is mount-bonded onto a lead frame 9 and connected thereto by wire 10. Light emitting element 11 is placed so as to face light receiving element 4 through a light-transmitting resin 12. The components described above are covered with a mold resin 13.

The optical semiconductor device of this embodiment is manufactured as below.

Mount bed 2 integrated with lead frame 1 is formed by molding an injection resin. Specifically, after the resin is poured into a predetermined mold and is heat cured, the resin is removed from the mold. Thus, mount bed 2 is integrally formed with lead frame 1. Discharge hole 6 is simultaneously formed so as to penetrate the mount bed in a region where the concave portion is formed due to the use of an ejector pin. The lead frame is removed from the mold by use of the ejector pin to push the lead frame off and concave portion 5 is formed. In this event, concave portion 5 is formed so as have one end of discharge hole 6 in its center.

Next, adhesive agent 3 is applied on mount bed 2 including concave portion 5 described above and light receiving element 4 is mounted thereon. Concave portion 5 is not completely filled with adhesive agent 3 having predetermined viscosity. Accordingly, air bubbles are formed of air trapped between light receiving element 4 and mount bed 2. However, the air bubbles are removed through discharge hole 6. Here, the predetermined viscosity is assumed to be viscosity which does not cause variation in the applied amount.

After MOS-FET 8 is mount-bonded onto lead frame 1, MOS-FET 8 is connected to light receiving element 4 by wire 7. Light emitting element 11 is mount-bonded onto lead frame 9 and is connected thereto by wire 10.

Light receiving element 4 and the light emitting element 11 are placed to face each other and a space therebetween is sealed with light-transmitting resin 12. After light-transmitting resin 12 is heat cured, the components described above are covered with mold resin 13.

In this event, since no air bubbles are formed in concave portion 5, there are no air bubbles moving into and remaining in light-transmitting resin 12. Therefore, good optical coupling properties (photosensitivity) and withstand pressure between input and output are obtained. Moreover, manufacturing yield is improved by 10% or more.

Note that a shape and a position of discharge hole 6 are not particularly specified as long as discharge hole 6 penetrates mount bed 2 from concave portion 5. However, it is preferable that discharge hole 6 is formed in the center of concave portion 5. Discharge hole 6 is formed in the center in order to achieve improved discharge properties by discharge distance equalization. Moreover, a diameter of discharge hole 6 only need to be smaller than a short side of the mounted light receiving element (optical semiconductor element) and a diameter of the concave portion and is, for example, about 0.5 mmφ. When the diameter of discharge hole 6 is smaller than the short side of the optical semiconductor element and the diameter of the concave portion, the air trapped between the light receiving element and the concave portion can be discharged efficiently.

In this embodiment, the light emitting element and the light receiving element are provided so as to face each other. However, without being limited thereto, effects can be also obtained in a photocoupler and a photorelay which utilize reflected light. Specifically, in the photocoupler and the photorelay, a light receiving element and a light emitting element, which are mounted and bonded onto the same plane, are covered with a translucent optically coupling resin.

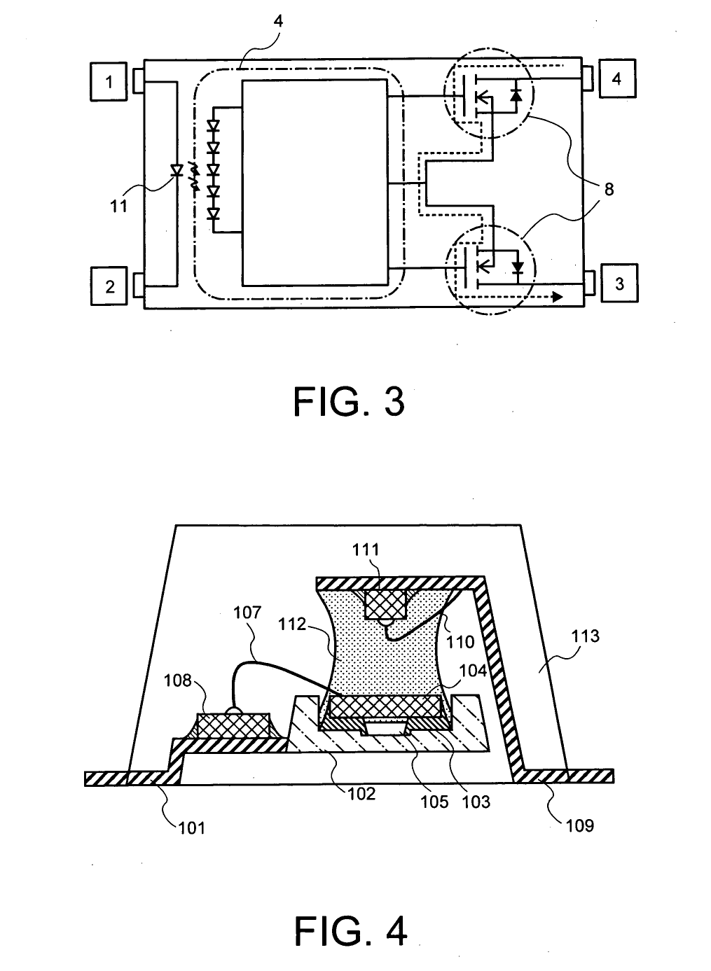

FIG. 3 is a view showing electrical connection of the optical semiconductor device. In the optical semiconductor device of this embodiment, as shown in FIG. 3, light from light emitting element 11 is converted into an electrical signal in light receiving element 4 and MOS-FET 8 in an output part is driven. Note that the dotted arrow indicates a current path when a + voltage is applied to 4 Pin. As described above, the optical semiconductor device described above can function as a high-speed switching device and the like.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

1. An optical semiconductor device comprising:
a lead frame;
a mount bed integrated with the lead frame;
an optical semiconductor element mounted on the mount bed with an adhesive agent interposed therebetween; and
a light-transmitting resin for sealing the optical semiconductor element,
wherein a surface of the mount bed mounting the optical semiconductor element has a concave portion and has one end of a discharge hole penetrating the mount bed in the concave portion.

2. The optical semiconductor device according to claim 1, wherein the optical semiconductor element is mounted on the discharge hole.

3. The optical semiconductor device according to claim 1, wherein the discharge hole is formed in the center of the concave portion.

4. The optical semiconductor device according to claim 1, wherein a diameter of the discharge hole is smaller than a short side of the optical semiconductor device and a diameter of the concave portion.

5. The optical semiconductor device according to claim 1, wherein the optical semiconductor element is a light receiving element.

6. The optical semiconductor device according to claim 5, further comprising:
a light emitting element which is sealed with the light-transmitting resin together with the light receiving element.

7. A method for manufacturing an optical semiconductor device, comprising:
integrally forming a lead frame having a predetermined shape and a mount bed by injection molding;
forming a discharge hole penetrating the mount bed at a predetermined position;
forming a concave portion on an upper surface of the mount bed including one end of the discharge hole;
applying an adhesive agent onto the upper surface of the mount bed including the concave portion;
mounting an optical semiconductor element on the adhesive agent; and
sealing the optical semiconductor element with a light-transmitting resin and heat curing the resin.

8. The method for manufacturing an optical semiconductor device according to claim 7, further comprising:
removing air bubbles in the concave portion, which are generated in application of the adhesive agent, through the discharge hole.

9. The method for manufacturing an optical semiconductor device according to claim 7, wherein the concave portion is formed so as to have one end of the discharge hole in its center.
